(19) United States
(12) Patent Application Publication
(10) Pub. No.: US 2026/0144001 A1
(43) Pub. Date: May 21, 2026

(54) GAS DIFFUSION APPARATUS AND SEMICONDUCTOR CONTAINER USING THE SAME

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); KUO-HUA LEE, New Taipei City (TW)

(73) Assignee: GUDENG PRECISION INDUSTRIAL CO., LTD., New Taipei City (TW)

(21) Appl. No.: 19/389,078

(22) Filed: Nov. 14, 2025

Related U.S. Application Data
(60) Provisional application No. 63/720,780, filed on Nov. 15, 2024.

(51) Int. Cl. H01L 21/673

(52) U.S. Cl. CPC H10P 72/1924

(57) ABSTRACT

The present disclosure provides a gas diffusion apparatus for a semiconductor container, to solve the problem of poor purging in the semiconductor container. The gas diffusion apparatus includes a diffuser body and a first portion and a second portion that are disposed on the diffuser body. The first portion has a first airflow rate, and the second portion has a second airflow rate. The first airflow rate is different from the second airflow rate. The present disclosure is applicable to cleaning and purging of the semiconductor container, to improve cleanliness of the semiconductor container.

### CROSS-REFERENCE TO RELATED APPLICATION

This non-provisional application claims priority under 35 U.S.C. § 119(e) on US provisional Patent Application No(s). 63/720,780 filed on Nov. 15, 2024, the entire contents of which are hereby incorporated by reference.

### BACKGROUND OF THE INVENTION

### 1. Field of the Invention

The present disclosure relates to a gas diffusion apparatus, and in particular, to a gas diffusion apparatus for improving a cleaning effect in a semiconductor container and a semiconductor container to which the same is applied.

### 2. Description of the Related Art

During manufacturing and transportation of semiconductors, to protect semiconductor workpieces (such as wafers, glass substrates, or sheet‑like articles), semiconductor containers are usually used to store, place, and transport the workpieces. In these containers, support members are usually disposed to support and load the semiconductor workpieces, and gas diffusion apparatuses are disposed to perform operations such as purging and ventilation in the containers, to remove particles generated due to vibration and friction of the semiconductor workpieces during transportation, or remove moisture or gases that are not expected to accumulate in the container.

With development of the semiconductor manufacturing process and requirements on a yield, cleanliness of the semiconductor containers and efficiency and reliability of the foregoing gas diffusion apparatuses become increasingly important. Therefore, how to effectively reduce particles and moisture in the semiconductor containers and improve efficiency of the gas diffusion apparatuses to reduce the impact of the particles and moisture on stored substrates and the process yield is of great importance.

### BRIEF SUMMARY OF THE INVENTION

However, when a conventional gas diffusion apparatus purges an accommodating space of a semiconductor container, the gas diffusion apparatus in the conventional technology cannot effectively control an airflow rate of gas at different heights of the container, which easily causes an excessive airflow rate in the upper layer and an insufficient airflow rate in the lower layer, causing a non-uniform purging effect. This leads to problems such as accumulation of particles or moisture at the lower level of the accommodating space of the semiconductor container. For another example, when N₂ is used as a purging gas, because the gas density of the N₂ is low, the airflow rate in the upper layer tends to be greater than that in the lower layer in the accommodating space, which causes uneven airflow rates and causes the foregoing problems of the poor purging effect between different layers, and accumulation of particles or moisture that cannot be smoothly removed, affecting the semiconductor process yield.

In view of this, the present disclosure aims to provide an improved gas diffusion apparatus, to overcome the foregoing problem of the poor purging effect in the prior art. According to the gas diffusion apparatus provided in the present disclosure, different levels of airflow rates can be provided, and a gas purging effect can be controlled in the accommodating space of the semiconductor container by providing different levels of airflow rates at different heights.

An aspect of the present disclosure provides a gas diffusion apparatus, applicable to the semiconductor container. The gas diffusion apparatus includes: a diffuser body; a first portion disposed on the diffuser body, the first portion having a first airflow rate; and a second portion disposed on the diffuser body, the second portion having a second airflow rate; where the first airflow rate is different from the second airflow rate.

In an embodiment, a density of the first portion is less than a density of the second portion, and the first airflow rate is greater than the second airflow rate.

In an embodiment, the first portion is a hollow portion, the second portion is a solid portion, a density of the hollow portion is less than a density of the solid portion, and the first airflow rate is greater than the second airflow rate.

In an embodiment, the first portion and the second portion are both hollow portions, a density of the first portion is less than a density of the second portion, and the first airflow rate is greater than the second airflow rate.

In an embodiment, the first portion and the second portion are of different materials.

In an embodiment, the first portion and the second portion are of the same material.

In an embodiment, the gas diffusion apparatus further includes a third portion, having a third airflow rate. The third airflow rate is different from the second airflow rate.

In an embodiment, the first portion, the second portion, and the third portion are sequentially disposed, and the first airflow rate, the second airflow rate, and the third airflow rate are sequentially increased or decreased.

In an embodiment, the first portion occupies a first proportion in the gas diffusion apparatus, and the second portion occupies a second proportion in the gas diffusion apparatus.

In an embodiment, a ratio of the first proportion to the second proportion is variable.

In an embodiment, the first proportion to the second proportion is 1:3.

Another aspect of the present disclosure provides a semiconductor container, including: a container body having an accommodating space; a support member, disposed in the accommodating space and adapted to support a substrate; and a gas diffusion apparatus disposed in the accommodating space, the gas diffusion apparatus having a diffuser body; a first portion disposed on the diffuser body, the first portion having a first airflow rate; and a second portion disposed on the diffuser body, the second portion having a second airflow rate, where the first airflow rate is different from the second airflow rate.

Therefore, through different portions of the gas diffusion apparatus of the present disclosure that are configured with different densities or different materials, the gas diffusion apparatus can control the airflow rate of each portion, to solve a problem that a difference in airflow rates between upper and lower layers of different support members causes a non-uniform purging effect.

In addition, configurations of different densities and different airflow rates can address the problem of poor purging effect, so that the airflow rate of the gas in the lower layer is greater than the airflow rate in the upper layer in the accommodating space. In addition, in the present disclosure, by controlling an internal density of the gas diffusion apparatus, the airflow rate can also be adjusted as required. For example, for a low-density gas such as N₂, the internal density can be adjusted to be higher at the upper part and to be lower at the lower part of the gas diffusion apparatus, to change the airflow rates at the upper part and the lower part, so that the gas replacement rate of the entire accommodating space is increased. When gas purging efficiency is increased, particles or moisture in the semiconductor container can be reduced, and the semiconductor process yield can be improved.

### BRIEF DESCRIPTION OF THE DRAWINGS

FIG. 1 shows a schematic three-dimensional exploded view of a semiconductor container according to an embodiment of the present disclosure.

FIG. 2 shows a schematic front view of a semiconductor container according to an embodiment of the present disclosure.

FIG. 3 shows a schematic cross-sectional diagram of a gas diffusion apparatus according to an embodiment of the present disclosure.

FIG. 4 shows a schematic cross-sectional diagram of a gas diffusion apparatus according to an embodiment of the present disclosure.

FIG. 5 shows a schematic cross-sectional diagram of a gas diffusion apparatus according to an embodiment of the present disclosure.

FIG. 6 shows a schematic diagram comparing purging effects of different configurations of a gas diffusion apparatus according to an embodiment of the present disclosure.

### DETAILED DESCRIPTION OF THE INVENTION

To describe the technical content of the present disclosure in detail, the following further describes the technical content with reference to implementations and drawings. It should be noted that in the content of this specification, terms such as "first", "second", and "third" are used to distinguish between different elements, but are not used to limit the elements or indicate a specific sequence of the elements. In addition, in the content of this specification, when no specific quantity is specified, the article "a" refers to one element or more than one element.

For full understanding of the objectives, features, and effects of the present disclosure, the present disclosure is described in detail below through the following specific embodiments with reference to the accompanying drawings.

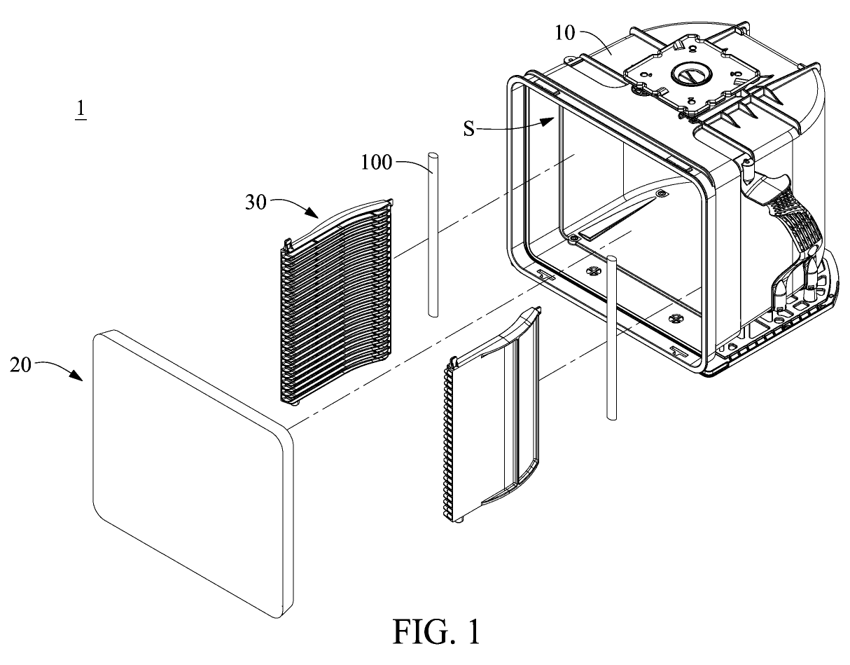

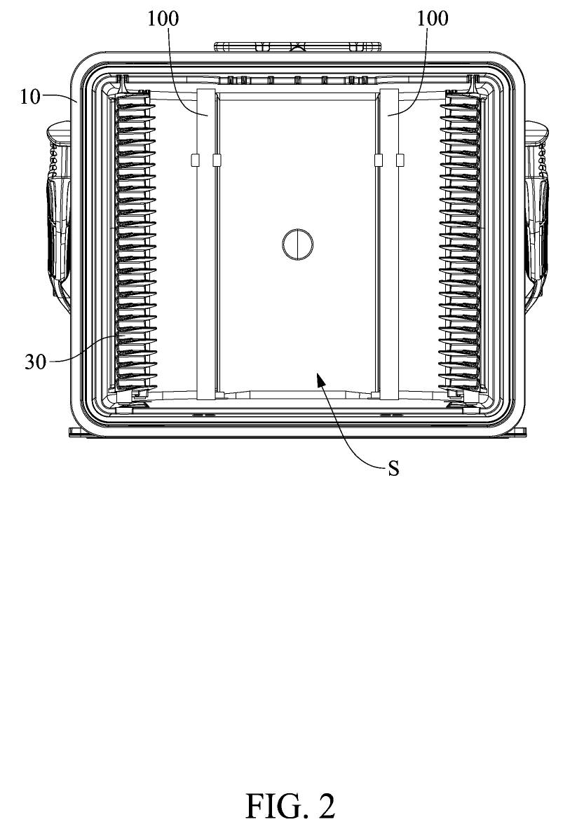

Refer to FIG. 1 and FIG. 2. FIG. 1 shows a schematic three-dimensional exploded view of a semiconductor container according to an embodiment of the present disclosure, and FIG. 2 shows a schematic front view of a semiconductor container according to an embodiment of the present disclosure. As shown in FIG. 1, a semiconductor container 1 includes a container body 10, a container door 20, a support member 30, and a gas diffusion apparatus 100. The container body 10 has an accommodating space S that can accommodate a semiconductor workpiece (such as a substrate). The container door 20 is adapted to selectively open or close an opening of the semiconductor container 1. The support member 30 is disposed in the accommodating space S of the semiconductor container 1, for example, disposed on two sides to support and carry the substrate.

As shown in FIG. 2, the gas diffusion apparatus 100 is disposed in the accommodating space S. The gas diffusion apparatus 100 is used to input a gas into the accommodating space S. In an embodiment, an example in which there are two gas diffusion apparatuses 100 is used. The two gas diffusion apparatuses 100 are disposed in the accommodating space S at a side away from the opening, for example, disposed at an inner side of a rear wall of the container body 10, so that a clean gas from the gas diffusion apparatuses 100 can be blown out in a direction toward the container opening. However, the quantity or disposition location of the gas diffusion apparatus 100 is not limited thereto. The support member 30 has a multi-layer bearing portion (also referred to as a gear rack), to bear a plurality of substrates (for example, there are 25 layers to bear 25 substrates). In addition, the gas diffusion apparatus 100 may be disposed in a direction perpendicular to a substrate bearing plane, so that gas purging can be provided to each layer of the bearing portion of the support member 30. For example, the gas purging from the gas diffusion apparatus 100 can be performed from the lowest layer (for example, the 1^{st} layer) to the topmost layer (for example, the 25^{th} layer) in the accommodating space S of the container body 10. A gas supply source is inputted into the gas diffusion apparatus 100 from the bottom of the container body 10.

As described in the part of the prior art, in some application scenarios, when a conventional gas diffusion apparatus is used to purge the accommodating space S of the semiconductor container 1, the container door 10 may be in an open state, and in this open environment, substances (such as humid air or particles) to be removed through purging in the container tend to flow downward. In this case, if N₂ is used as a purging gas, because a gas density of the N₂ is low, an airflow rate in the upper bearing portion of the support member 30 is greater than an airflow rate in the lower bearing portion, causing a non-uniform purging effect, so that the substances to be removed through purging easily accumulate in a range of the lower bearing portion of the support member 30, that is, moisture or mote particles easily accumulate in the accommodating space S at the bottom of the container body 10. Therefore, in exemplary embodiments of the present disclosure, the gas diffusion apparatus 100 includes a diffuser body 101, and a first portion and a second portion that are disposed on the diffuser body 101. The first portion and the second portion have different airflow rates, so that the diffuser body 101 can be adjusted to implement different airflow rates at different heights of the accommodating space S, thereby improving a purging effect.

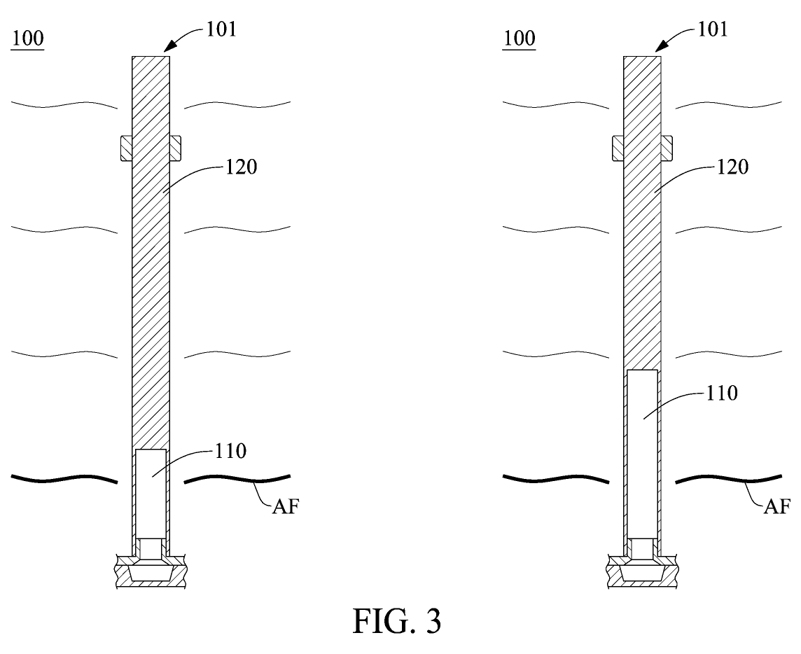

Referring to FIG. 2 and FIG. 3, FIG. 3 is a schematic cross-sectional diagram of a gas diffusion apparatus 100 according to an embodiment of the present disclosure. The gas diffusion apparatus 100 includes at least one diffuser body 101, and the first portion 110 and the second portion 120 that are disposed on the diffuser body 101. The first portion 110 and the second portion 120 may be connected to each other or may be separated from each other. The first portion 110 has a first airflow rate, the second portion 120 has a second airflow rate, and the first airflow rate is different from the second airflow rate. In this way, after a gas enters the diffuser body 101 (for example, enters from below), the gas is blown out through the first portion 110 and the second portion 120 of the diffuser body 101, and airflows AFs flowing out of the first portion 110 and the second portion 120 respectively have different airflow rates.

Through a design of different airflow rates of the first portion 110 and the second portion 120, airflow rates of different regions in the accommodating space of the semiconductor container 1 can be adjusted as required, thereby achieving the purging effect in the different regions. For example, when substances to be purged accumulate in a bottom layer of the accommodating space S, an airflow rate in the bottom layer can be increased to improve the purging effect in the bottom layer. If the first portion 110 is disposed at the bottom of the diffuser body 101 (corresponding to the bottom layer of the accommodating space S), and the first portion 110 is disposed at the upper-middle part of the diffuser body 101 (corresponding to the upper-middle layer of the accommodating space S), it can be set that the first airflow rate of the first portion 110 is greater than the second airflow rate of the second portion 120, to improve the purging effect in the bottom layer of the accommodating space S. For another example, as described above, when the clean gas is N₂, a lower airflow rate can be set in the upper portion, for example, the second portion 120, of the accommodating space S of the diffuser body 101, and a higher airflow rate can be set in the lower portion, for example, the first portion 110, of the accommodating space S. In this way, the airflow rate at the upper layer of the bearing portion of the support member 30 is reduced, and the airflow rate at the lower layer of the bearing portion of the support member 30 is increased, thereby achieving a uniform purging effect.

In an embodiment, a density of the first portion 110 is less than a density of the second portion 120, so that the first airflow rate is greater than the second airflow rate. For example, when the gas supply source enters the gas diffusion apparatus 100 from the bottom of the container body 10, the gas is blown through the first portion 110 of the diffuser body that has the lower density and the second portion 120 of the diffuser body that has the higher density, thereby delivering the clean gas into the accommodating space S. In this case, because the first portion 110 has the lower density, the gas tends to accumulate in the first portion 110 to be blown outward, and the higher density of the second portion 120 results in a smaller airflow volume that accumulates in the second portion 120 to be blown out, thereby achieving an effect that the first airflow rate is greater than the second airflow rate. As shown in FIG. 3, an airflow AF blown out from the first portion 110 is thicker than an airflow AF blown out from the second portion 120, to represent a difference in the airflow rates. In addition, by changing or adjusting the density of the first portion 110 and the density of the second portion 120, the airflow rate of the first portion 110 and the airflow rate of the second portion 120 can be further controlled, to improve airflow distribution and airflow condition, thereby achieving a desired gas purging effect.

As described above, a density difference of the first portion 110 and the second portion 120 includes a density difference in materials forming the first portion 110 and the second portion 120, for example, a pore size, a particle size, a material density, and a void size, but is not limited thereto, and a density difference when the first portion 110 or the second portion 120 of the diffuser body 101 is considered as a whole. For example, if the first portion 110 and the second portion 120 are totally the same in external volume and material, but some regions in the first portion 110 are hollow, the density of the first portion 110 is referred to as being less than the density of the second portion 120. Therefore, the density difference of the first portion 110 and the second portion 120 only needs to differ in an overall density, and make a difference in flow, pressure, accumulation, flow velocity, flow rate, flow direction, and the like of the gas. This is not limited to the examples cited above.

It should also be noted that, a distribution manner of the first portion 110 and the second portion 120 is not limited to what is shown in the figure. The distribution manner of the first portion 110 and the second portion 120 may be continuously connected or may be intermittently connected. For example, another non-ventilated interval region may be disposed between the first portion 110 and the second portion 120. In addition, a distribution difference between the first portion 110 and the second portion 120 is also not limited to a height direction, and the first portion 110 and the second portion 120 may also be distributed in different forms in other directions or parts such as a transverse direction, an axial direction, a radial direction, an inner-outer direction, or an irregular direction.

In an embodiment, as shown in FIG. 3, the first portion 110 is a hollow portion, the second portion 120 is a solid portion, and the first airflow rate (a thicker airflow AF schematic line) of the first portion 110 is greater than the second airflow rate (a thinner airflow AF schematic line) of the second portion 120. In this case, it may also be referred to as that the density of the first portion 110 is less than the density of the second portion 120. In this way, after the gas enters the gas diffusion apparatus 100 (for example, enters from below), the gas passes through the hollow first portion 110 and the solid second portion 120 of the gas diffusion apparatus 100, and flows out from the first portion 110 and the second portion 120 respectively, and the airflows AFs flowing out of the hollow first portion 110 and the solid second portion 120 have different airflow rates.

It should be noted that the term "solid" used here does not mean that the gas cannot pass through the solid portion. Rather, relative to the hollow material-free portion, the solid portion still has filling of a material through which the gas can pass, for example, is a solid sintered particle structure. The solid sintered structure can also be further distinguished into different density structures of solid sintered coarse particles and solid sintered fine particles. That is, even the solid portion can still have different material densities. In an embodiment, the hollow portion is formed by a sintered hollow tube, and the solid portion is formed by particles of different sizes of solid sintered coarse particles or solid sintered fine particles. In an embodiment, the aforementioned materials are all porous materials.

In an embodiment, the first portion 110 and the second portion 120 may be made of the same material, that is, the first portion 110 and the second portion 120 are integrally of the same material. However, the first portion 110 and the second portion 120 may have different set densities, different internal solid or hollow structures, and the like, to provide different airflow rates. For example, the first portion 110 and the second portion 120 can achieve different overall densities and different airflow rates through different structural designs, for example, designs such as a porosity and a solid/hollow ratio.

In an embodiment, the first portion 110 and the second portion 120 may be made of different materials, for example, the foregoing sintered structures of different particle sizes, or screens and filters of different pore sizes, to achieve different densities. It should be noted that the materials of the first portion 110 and the second portion 120 are the same or different. The materials may cover parts of the first portion 110 and the second portion 120, such as an inner part or a surface layer, and are not limited thereto.

In an embodiment, the first portion 110 and the second portion 120 have different proportions in the gas diffusion apparatus 100, that is, different distribution proportions, such as different distributions in length and height, to adjust different airflow rates and specific airflow positions corresponding to the different airflow rates.

In an embodiment, the first portion 110 occupies a first proportion in the gas diffusion apparatus 100, and the second portion 120 occupies a second proportion in the gas diffusion apparatus 100. For example, as shown in the schematic diagram on the left and the schematic diagram on the right of FIG. 3, the first portion 110 and the second portion 120 have different proportions in distribution of the overall diffuser body 101.

In an embodiment, a ratio of the first proportion to the second proportion is variable, that is, the ratio of the first proportion to the second proportion can be further adjusted based on a desired airflow rate in each region (for example, corresponding to each layer of support member in a height direction), to obtain different airflow rate distributions. In an embodiment, the first proportion to the second proportion is approximately 1:3, that is, the first proportion accounts for approximately 1/4 of the entire diffuser body 101, so that a bottom-layer region in which the substances to be purged originally easily accumulate can have a large airflow rate, thereby achieving uniform purging of the entire accommodating space. In addition, when the first proportion to the second proportion is approximately 1:3, the first portion 110 is hollow, and the second portion 120 is solid and is of low-density sintered material, the purging effect is optimal at the lowest layer of the accommodating region, which corresponds to the substrate of the lower layer (for example, the 1^{st} layer) of the bearing portion of the support member, and a moisture rebound rate can be reduced by approximately 50%. Details are provided below.

In an embodiment, the first proportion to the second proportion is 3:4, so a lower region in which the substances to be purged originally easily accumulate can have a large airflow rate, thereby improving the purging effect of the entire accommodating space. In an embodiment, a hollow pore depth of the first portion 110 is 54 mm. In an embodiment, the hollow pore depth of the first portion 110 is 94 mm. In an embodiment, the shape of the gas diffusion apparatus 100 is an elliptical tube.

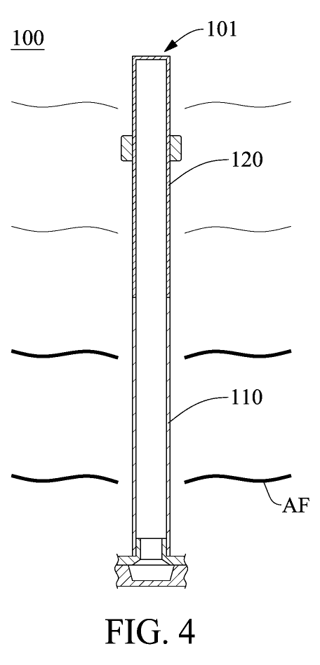

Referring to FIG. 4, FIG. 4 is a schematic cross-sectional diagram of another embodiment of the gas diffusion apparatus 100 according to the present disclosure. The first portion 110 and the second portion 120 of the diffuser body 101 are both hollow portions, and the density of the first portion 110 is less than the density of the second portion 120, so that the first airflow rate is greater than the second airflow rate. An outer layer of the first portion 110 may also be referred to as a housing of the gas diffusion apparatus 100. Densities of the outer layer of the first portion 110 and an outer layer of the second portion 120 are different. A density of the outer layer of the first portion 110 is less than a density of the outer layer of the second portion 120, and the outer layers are indicated by dashed lines of different densities, so that the first airflow rate of the first portion 110 is greater than the second airflow rate of the second portion 120. However, it should be noted that the thickness of the housing described herein is not limited, and the housing is not simply limited to the "housing" or "outer layer". Any structure that is partially hollow internally and exhibits a difference in overall density falls within the scope of this disclosure. In this way, through a design in which the first portion 110 and the second portion 120 are both hollow but the densities and/or the materials are different, a difference in the airflow AF volumes of the airflow rates can also be achieved.

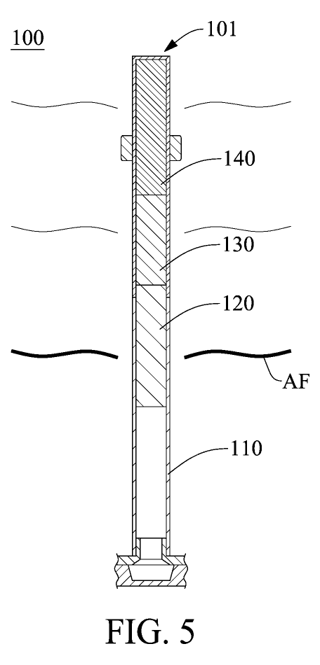

Referring to FIG. 5, FIG. 5 is a cross-sectional schematic diagram of another embodiment of a gas diffusion apparatus 100 according to the present disclosure. The gas diffusion apparatus 100 further has a third portion 130, the third portion 130 is disposed on the diffuser body 101, the third portion 130 has a third airflow rate, and the third airflow rate is different from the second airflow rate. Certainly, based on gas purging requirements for different cleanliness levels, the third airflow rate, the second airflow rate, and the first airflow rate may be the same, partially the same, or different. Alternatively, the third airflow rate, the second airflow rate, and the first airflow rate may be sequentially increased or decreased. As described in the foregoing embodiments, materials of the third portion 130 and the first portion 110 and/or the second portion 120 may be the same or different, and densities of the third portion 130 and the first portion 110 and/or the second portion 120 may be the same or different. The third portion 130 may also be hollow or solid, to adjust configuration based on an actual requirement, and flexibly adjust airflow rates of different portions.

In an embodiment, the gas diffusion apparatus 100 may further include a fourth portion 140, and the fourth portion 140 is disposed on the diffuser body 101. The fourth portion 140 has a fourth airflow rate. It should be noted that quantity, material, hollow or solid structure, density and the like of each portion need not to be completely different, and different permutations and combinations may be configured for the parameters based on actual requirements, to obtain different airflow rates in the portions.

In an embodiment, as shown in FIG. 5, the gas diffusion apparatus 100 includes the diffuser body 101, the first portion 110, the second portion 120, the third portion 130, and the fourth portion 140 that are located on the diffuser body 101. The first portion 110, the second portion 120, the third portion 130, and the fourth portion 140 are sequentially connected from bottom to top, and the density of each portion also sequentially increases. Through a multi-segment design, an airflow ratio of the portions of the diffuser body 101 can be adjusted more precisely, to finely adjust the purging effect of the gas diffusion apparatus 100 on the accommodating space S of the semiconductor container 1.

As disclosed in the foregoing embodiments, through permutations and combinations using same or different densities and/or materials, the gas diffusion apparatus 100 in the embodiments of the present disclosure can provide different airflow rates at different portions based on different design requirements, thereby addressing problems such as accumulation of particles or moisture at different positions or regions in the accommodating space of the semiconductor container, and achieving a more beneficial purging and cleaning effect. For another example, through permutations and combinations of same or different densities and/or materials in each portion of the gas diffusion apparatus 100, problems such as excessively high air pressure, excessively fast airflow, and excessively small airflow in some regions can also be resolved, and an airflow rate of a required portion can also be adjusted based on an actual requirement scenario, thereby achieving the effect that the airflow rate of each portion can be controlled by only adjusting a structure and a material of the gas diffusion apparatus 100.

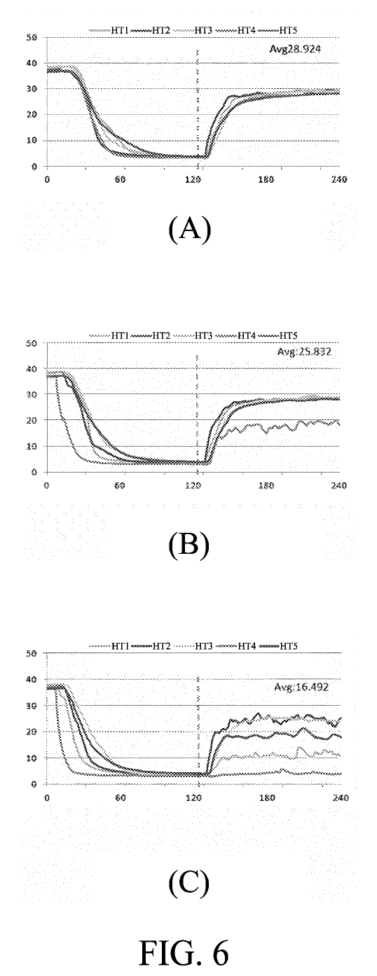

Referring to FIG. 6, FIG. 6 shows a schematic diagram comparing purging effects of different configurations of a gas diffusion apparatus according to an embodiment of the present disclosure. FIG. 6 shows a change status of humid air measured at each part in the bottom layer of the accommodating space S, for example, at the lower layer (for example, the 1^{st} layer) of the bearing portion of the support member. Data lines represent graphs of a moisture-to-time ratio at different positions in the accommodating space S. HT1 corresponds to a middle part of the container bottom, HT2 corresponds to a part close to the opening at the container bottom, HT4 corresponds to a part close to the rear wall at the container bottom, and HT3 and HT5 correspond to two sides of HT1. A part (A) of FIG. 6 displays that an average value of hollow tube fine particles in the configuration is 28.924, a part (B) of FIG. 6 displays that an average value of 1/2 solid coarse particles in the configuration is 25.832, and a part (C) of FIG. 6 displays that an average value of 3/4 solid fine particles is 16.492. Therefore, it can be seen that, the gas diffusion apparatus 100 according to the embodiments of the present disclosure can effectively reduce rebound of substances, such as moisture, in the bottom layer of the container, and can improve the purging effect in the bottom layer. In addition, the porous gas diffusion apparatus with different proportional sections in the embodiments of the present disclosure can control an airflow rate of the purging gas based on the porous material of the hollow portion and the solid portion in the different proportional sections. It is shown according to the experimental result of FIG. 6 that, a configuration in which the first proportion to the second proportion is approximately 1:3 (3/4 is solid and is of low-density sintered material) performs well in the bottom layer (the 1^{st} layer) of the accommodating space S. The configuration reduces the moisture rebound rate by approximately 50%, and can effectively reduce the moisture rebound rate at the lower layer of the accommodating space. In addition, the moisture rebound of the bottom layer (the 1^{st} layer) of the accommodating space S is sequentially as follows: three quarters of the solid sintered coarse particles > the half-tube solid sintered fine particles > the sintered hollow tube.

The present disclosure is disclosed above through the exemplary embodiments. However, a person skilled in the art should understand that the embodiments are merely used for describing the present disclosure, but should not be construed as limiting the scope of the present disclosure. It should be noted that any equivalent change or replacement with the embodiments should be covered in the scope of the present disclosure. Therefore, the protection scope of the present disclosure shall be subject to what is defined by the scope of the appended claims, and the scope of the appended claims should be interpreted in the broadest sense, to include all such modifications and similar arrangements and processes therein.

While the present disclosure has been described by means of specific embodiments, numerous modifications and variations could be made thereto by those skilled in the art without departing from the scope and spirit of the present disclosure set forth in the claims.

What is claimed is:

1. A gas diffusion apparatus, applicable to a semiconductor container, the gas diffusion apparatus comprising:
at least one diffuser body;
a first portion disposed on the diffuser body, the first portion having a first airflow rate; and
a second portion disposed on the diffuser body, the second portion having a second airflow rate; wherein
the first airflow rate is different from the second airflow rate.

2. The gas diffusion apparatus according to claim 1, wherein a density of the first portion is less than a density of the second portion, and the first airflow rate is greater than the second airflow rate.

3. The gas diffusion apparatus according to claim 1, wherein the first portion is a hollow portion, the second portion is a solid portion, a density of the hollow portion is less than a density of the solid portion, and the first airflow rate is greater than the second airflow rate.

4. The gas diffusion apparatus according to claim 1, wherein the first portion and the second portion are both hollow portions, a density of the first portion is less than a density of the second portion, and the first airflow rate is greater than the second airflow rate.

5. The gas diffusion apparatus according to claim 1, wherein the first portion and the second portion are of different materials.

6. The gas diffusion apparatus according to claim 1, wherein the first portion and the second portion are of the same material.

7. The gas diffusion apparatus according to claim 1, wherein the gas diffusion apparatus further comprises a third portion having a third airflow rate, wherein the third airflow rate is different from the second airflow rate.

8. The gas diffusion apparatus according to claim 7, wherein the first portion, the second portion, and the third portion are sequentially disposed, and the first airflow rate, the second airflow rate, and the third airflow rate are sequentially increased or decreased.

9. The gas diffusion apparatus according to claim 1, wherein the first portion occupies a first proportion of the diffuser body, and the second portion occupies a second proportion of the diffuser body.

10. The gas diffusion apparatus according to claim 9, wherein a ratio of the first proportion to the second proportion is variable.

11. The gas diffusion apparatus according to claim 9, wherein the first proportion to the second proportion is 1:3.

12. A semiconductor container, comprising:
a container body having an accommodating space;
a support member disposed in the accommodating space and adapted to support a substrate; and
a gas diffusion apparatus disposed in the accommodating space, the gas diffusion apparatus comprising:
a diffuser body;
a first portion disposed on the diffuser body, the first portion having a first airflow rate; and
a second portion disposed on the diffuser body, the second portion having a second airflow rate; wherein
the first airflow rate is different from the second airflow rate.
